(19) United States
(12) Patent Application Publication
(10) Pub. No.: US 2008/0285251 A1
(43) Pub. Date: Nov. 20, 2008

(54) Packaging Substrate with Flat Bumps for Electronic Devices and Method of Manufacturing the Same

(75) Inventors: Jerry Liang, Xinzhu County (TW); Jieren Xie, Jiangsu (CN); Xinchao Wang, Jiangsu (CN); Xiekang Yu, Jiangsu (CN); Yujuan Tao, Jiangsu (CN); Rongfu Wen, Jiangsu (CN); Fushou Li, Jiangsu (CN); Zhengwei Zhou, Jiangsu (CN); Da Wang, Jiangsu (CN); Haibo Ge, Jiangsu (CN); Qiang Zheng, Jiangsu (CN); Zhen Gong, Jiangsu (CN); Weijun Yang, Jiangsu (CN)

Correspondence Address: HESLIN ROTHENBERG FARLEY & MESITI PC, 5 COLUMBIA CIRCLE, ALBANY, NY, 12203, US

(73) Assignee: Jiangsu Changiang Electronics Technology Co., Ltd., Jiangyin (CN)

(21) Appl. No.: 11/910,893

(22) PCT Filed: Apr. 6, 2006
(86) PCT No.: PCT/CN2006/000608

§ 371 Date: May 16, 2008

(30) Foreign Application Priority Data
Apr. 7, 2005 (CN) 200510038818.3
May 27, 2005 (CN) 200510040261.7
May 27, 2005 (CN) 200510040262.1
Jul. 2, 2005 (CN) 200510041043.5
Jul. 2, 2005 (CN) 200510041044.X
Jul. 5, 2005 (CN) 200510041069.X
Jul. 5, 2005 (CN) 200510041070.2
Jul. 18, 2005 (CN) 200510041274.6
Jul. 18, 2005 (CN) 200510041275.0

(51) Int. Cl. H05K 7/18; H01R 43/00

(52) U.S. Cl. 361/813; 29/827

(57) ABSTRACT

A packaging substrate with fiat bumps for an electronic device and a method of manufacturing the same relate to the production of the packaging substrate for an electronic device, which comprises base islands and pins structurally and wherein the base islands and pins which all exhibit flat bump shape distribute on the front face of the substrate; the bottom side of the bumps, namely the rear faces of the base islands and pins are contiguous in the same substrate; in the packaging body of a single electronic device to be formed in later procedure, one or more base island may be included, the pins may arrange on one single side of the base island, also may arrange on the both sides or three sides of the base island, or may surround the base island so as to form the structure of one or more circuits of pins. The method includes that take a metal substrate is prepared, mask layers are adhered onto both sides of the metal substrate, the parts of the mask layers which need to be etched are removed, then half-etching is performed to form the recessed half-etching area, and then the residual mask layers on the metal substrate are removed to product the packaging substrate with flat bumps.

### CROSS-REFERENCE TO RELATED APPLICATIONS

This application is a §371 filing of PCT application CN2006/000608 which claims priority from Chinese application 200510038818.3 filed on Apr. 7, 2005, Chinese application 200510040262.1 filed on May 27, 2005, Chinese application 200510040261.7 filed on May 27, 2005, Chinese application 200510041044.X filed on Jul. 2, 2005, Chinese application 200510041043.5 filed on Jul. 2, 2005, Chinese application 200510041069.X filed on Jul. 5, 2005, Chinese application 200510041070.2 filed on Jul. 5, 2005, Chinese application 200510041275.0 filed on Jul. 18, 2005 and Chinese application 200510041274.6 filed on Jul. 18, 2005. The disclosures of these applications are hereby included by reference herein in their entirety.

### FIELD OF THE INVENTION

The present invention relates to a packaging substrate with flat bumps for electronic devices and a method of manufacturing the substrate, and belongs to the technical field of manufacturing of packaging substrates for electronic devices.

### BACKGROUND OF THE INVENTION

The traditional leadless flat bond packaging substrates for integrated circuits or discrete devices are lead frames in array form. They mainly have the following drawbacks:

1. Lead frame: since the lead frame is fabricated through a penetrative etching process, the lead frame structure is mild, and will be subject to deformation if it is produced with high-purity copper material. Therefore, such lead frames can't be produced with high-purity copper material to improve electrical and thermal properties.

2. Flexibility: limited by the lead frame structure, the pins and islands have to be arranged in a fixed manner. Therefore, the flexibility is low.

3. Outer lead pin structure: since the lead frame is fabricated through a penetrative etching process, the outer lead pins will be flush to the molded body and will not protrude from the molded body after encapsulation. Therefore, the soldering strength is often not enough after the outer lead pins are soldered to a printed circuit board on one side. In addition, in the surface bonding process, short circuit may occur in the Sn paste on the outer pins under pressure.

4. Major effects on encapsulation:

A. The lead frame has to be coated with a special glue film on the back: in order to complete the subsequent encapsulation procedures, the lead frame has to be coated with a special glue film on the back to prevent the packaging material from overflow to the back of the lead frame under high pressure. As a result, the material cost is increased.

B. Contamination from the glue film: in the subsequent encapsulation procedures, which are carried out under high temperature, the chemical substances in the glue film may volatilize and thereby causes contamination to the lead frame and chip. In that situation, an additional cleaning procedure will be required.

C. Soldering points on inner lead pins: since the lead frame is fabricated through a penetrative etching process, the lead frame must be coated with a glue film on the back to prevent material overflow. However, since the glue film is soft, the inner pins may displace in the wiring process because they are bonded to the soft glue film. As a result, loose soldering points may occur on the inner pins.

D. Encapsulation of molded body: since the lead frame structure is fabricated through a penetrative etching process, the lead frame must be coated with a glue film on the back to prevent material overflow. However, such an approach still can't suppress overflow completely. In addition, in order to prevent material overflow in a large area in the encapsulation process, usually the encapsulation process has to be carried out under a lower pressure, which may further cause loose encapsulation, increased water absorption rate, and decreased density, etc.

### BRIEF SUMMARY OF THE INVENTION

### Technical Problem

In order to overcome above drawbacks, the present invention provides a packaging substrate with flat bumps for electronic devices and a method of manufacturing the packaging substrate, which are featured with flexibility, short development cycle, wide applicability, and high solderability, etc., and can avoid the problems such as loose contact at soldering points, delamination in the package body, and overflow of the package material, etc., and thereby optimize the product structure of integrated circuits or discrete devices, and set a good foundation for improving product reliability and strength.

### Technical Solution

The packaging substrate with flat bumps for electronic devices provided in the present invention comprises a base island and lead pins, wherein the base island and the lead pins are distributed on the front of the substrate in the form of bumps, with the bottom of the bumps, that is base island and the back of the lead pins, are connected to the same substrate. In the package body for electronic device that is formed in the subsequent encapsulation process, the number of the islands can be one or several, the pins can be arranged on one side, two sides, or three sides of the island, or around the island, to form a structure with one or more rows of pins.

The following options are available for the structure:

The pins are coated with another metal layer on the front. Or, the pins are coated with an active substance on the front, with a metal layer coated on the active substance.

Both the pins and the island are coated with a metal layer on the front. Or both the pins and the islands are coated with an active substance on the front, with a metal layer coated on the active substance.

Both the pins and the island are coated with a metal layer on the back. Or both the pins and the islands are coated with an active substance on the back, with a metal layer coated on the active substance.

The pins are coated with a metal layer on the front and back, and the island is coated with a metal layer on the back; or the pins are coated with an active substance on the front and back and the island is coated with an active substance on the back, with a metal layer coated on the active substance.

Both the pins and the island are coated with a metal layer on the front and back. Or both the pins and the islands are coated with an active substance on the front and back, with a metal layer coated on the active substance.

Said metal layer covering on the substrate can cover the substrate partially or entirely.

Said metal layer is select from the group of Au, Ag, Cu, Sn, Ni, or Ni—Pd, and the said metal layer can comprise one or more layers, or is distributed partially. Said active substance is Ni, Pd, or Ni—Pd.

The method of manufacturing the packaging substrate with flat bumps for electronic device provided in the present invention comprises the following procedures:

1) Taking a metal substrate;

2) Bonding a film on the front and back of the metal substrate;

3) Removing the film on the front of the metal substrate partially, to expose the area to be semi-etched on the substrate;

4) Carrying out semi-etching in the area where the film is removed in the previous procedure, to form a recessed semi-etched area on the metal substrate and form an island and pins in the form of bumps;

5) Removing the residual film on the metal substrate, to obtain a packaging substrate with flat bumps;

6) Carrying out further processing for the packaging substrate with flat bumps as required.

The further processing can comprises the following procedures:

1) Coating a film on the front and back of the metal substrate including the area with bumps again;

2) Removing the film on the metal substrate partially, to expose the area to be coated with a metal layer subsequently;

3) Coating the area where the film is removed in the previous procedure with a metal layer;

4) Removing residual film on the metal substrate 6.

In above procedures, an active substance can be coated before the metal layer is coated.

### Beneficial Effects

The method of manufacturing the packaging substrate with flat bumps are featured with flexibility, short development cycle, wide applicability, and high solderability, etc., and can avoid the problems such as loose contact at soldering points, delamination in the package body, and overflow of the package material, etc., and thereby optimize the product structure of integrated circuits or discrete devices, and set a good foundation for improving product reliability and strength. In detail:

1. Lead frame: since the substrate is manufactured through a semi-etching process, the substrate structure is rigid. Therefore, the substrate can't be made of high-purity copper material, so as to improve electrical/thermal properties.

2. Flexibility: since a semi-etching process is used, the pins and the island can be arranged flexibly. Therefore, the product is flexible and can be developed in a short development cycle.

3. Outer lead pin structure: since the substrate is fabricated through a semi-etching process, the outer lead pins can protrude from the bottom of the molded body after the subsequent encapsulation process. Therefore, when the structure is soldered to a printed circuit board, the entire protruding surface of the outer pins can be coated with Sn paste, and thereby can be welded more easily and deliver higher strength; in addition, in the surface bonding procedure, the Sn paste will extend to cover the entire surface of the outer pins, as a result, short circuit in the Sn paste resulted from accumulation of the Sn plate on bottom of the pins can be avoided.

4. Major effects on encapsulation:

A. The substrate needn't to be coated with a special glue film on the back. Since the substrate needn't to be coated with a special glue film on the back to complete the entire encapsulation process, no contamination related to the glue film will occur. Therefore, the material cost and rework cost will be reduced.

B. Soldering points on inner pins: since the substrate is fabricated through a semi-etching process, the bottom of the pins is still connected to the substrate to form an integral structure. Therefore, the pins will be stable and will not displace in the wiring process, and the problem of loose contact at the soldering points will be avoided.

C. Encapsulation of molded body: since the substrate is fabricated through a semi-etching process, the bottom of the pin is still connected to the substrate to form an integral structure. Therefore, the packaging material can't penetrate the integral metal material in the encapsulation process, and therefore material overflow can be avoided; furthermore, since material overflow can be avoided, a higher encapsulation pressure can be used to increase density of the packaging material, reduce water absorption rate, and improve product reliability.

### BRIEF DESCRIPTION OF THE DRAWINGS

These, and other objects, features and advantages of this invention will become apparent from the following detailed description of the various aspects of the invention taken in conjunction with the accompanying drawings, in which:

FIGS. 1-9 are schematic diagrams of the method and procedures for manufacturing the substrate with flat bumps for electronic devices in the present invention. Wherein, FIG. 9 is a schematic diagram of a structure in which the pins and island are coated with a metal layer on the front and back;

FIG. 10 is a schematic diagram of a structure in which the pins are coated with a metal layer 4 on the front;

FIG. 11 is a schematic diagram of a structure in which the pins are coated with an active substance on the front, with a metal layer coated on the active substance;

FIG. 12 is a schematic diagram of a structure in which the pins and island are coated with a metal layer on the front;

FIG. 13 is a schematic diagram of a structure in which the pins and island are coated with an active substance on the front, with a metal layer coated on the active substance;

FIG. 14 is a schematic diagram of a structure in which the pins and island are coated with a metal layer on the back;

FIG. 15 is a schematic diagram of a structure in which the pins and island are coated with an active substance on the back, with a metal layer coated on the active substance;

FIG. 16 is a schematic diagram of a structure in which the pins are coated with a metal layer on the front and the back and the island is coated with a metal layer on the back;

FIG. 17 is a schematic diagram of a structure in which the pins are coated with an active substance on the front and back and the island is coated with an active substance on the back, with a metal layer coated on the active substance;

FIG. 18 is a schematic diagram of a structure in which the pins and island are coated with an active substance on the front and back, with a metal layer coated on the active substance.

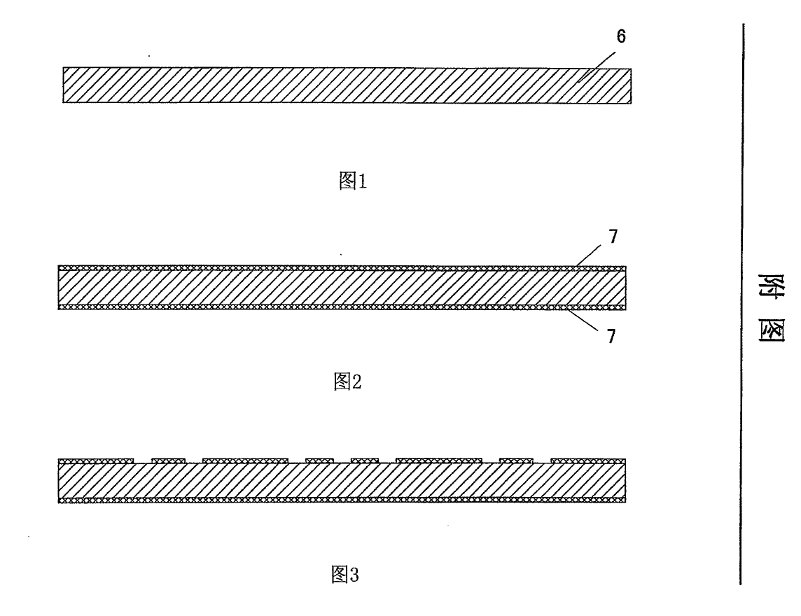

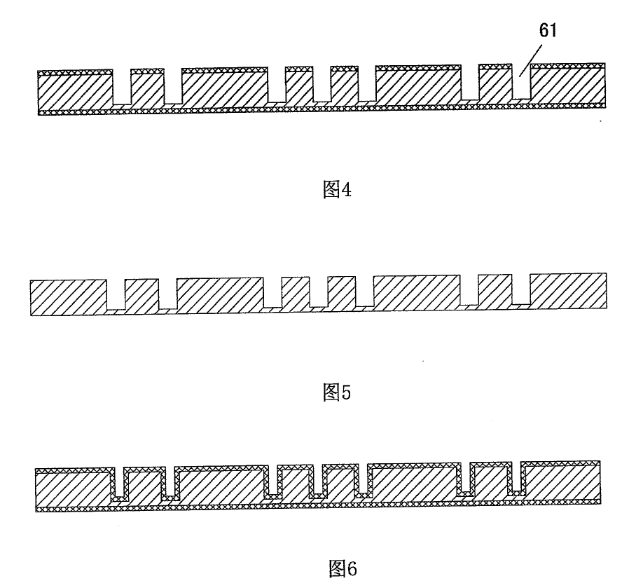

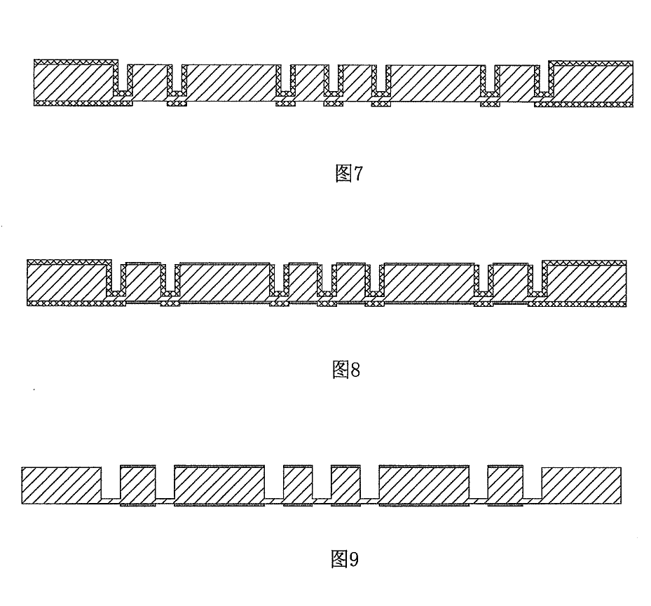

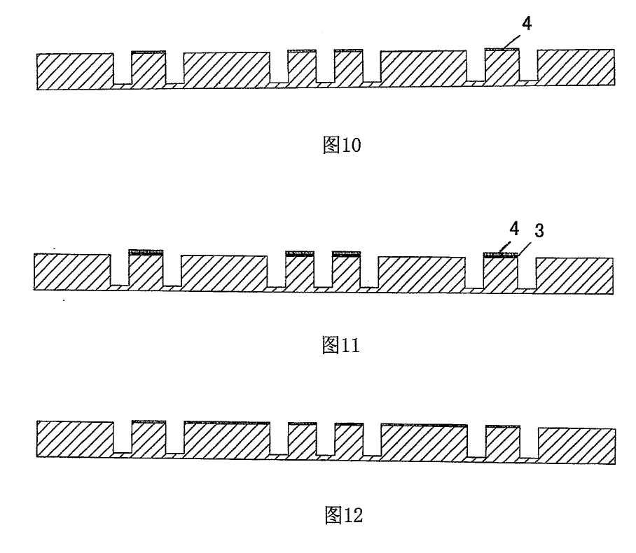

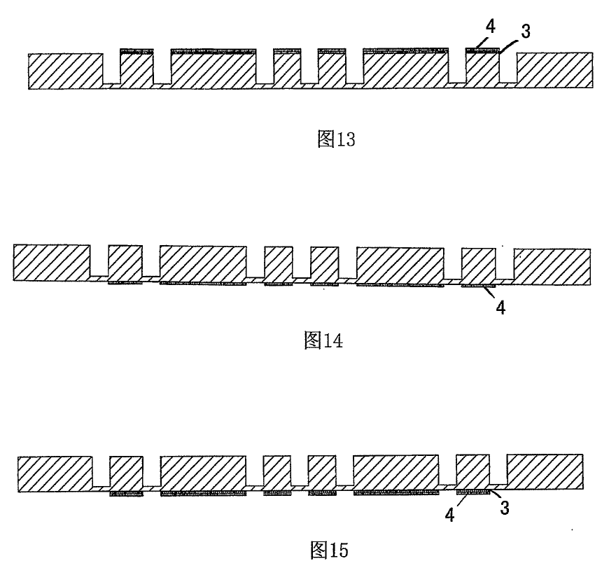

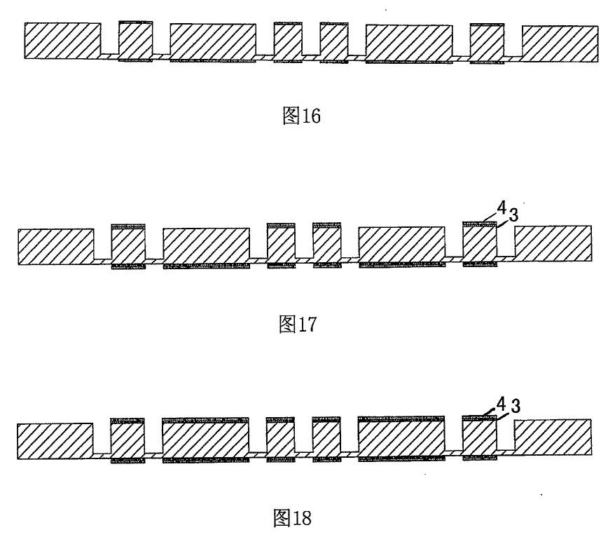

Brief Instruction to the Symbols: 1—Base island; 2—Lead pin; 3—Active substance; 4—Metal layer; 5—Metal substrate; 61—Semi-etching area; 7—Film.

### DETAILED DESCRIPTION OF THE PREFERRED EMBODIMENTS

The packaging substrate with flat bumps for electronic devices in the present invention comprises an island 1 and lead pins 2, wherein, the island 1 and lead pins 2 are distributed on the front of the substrate in the form of bumps, and the bottoms of the bumps, that is the backs of island 1 and pins 2, are connected to the substrate; in such an encapsulation structure for electronic device that is formed in the subsequent encapsulation process, the number of the islands can be one or several, and the pins can be arranged on one side, two sides, or three sides of the island, or around the island to form a structure with one or more rows of pins.

The following options are available for the structure:

The pins are coated with a metal layer 4 on the front.

The pins are coated with an active substance on the front, with a metal layer coated on the active substance.

Both the pins and the island are coated with a metal layer on the front.

Both the pins and the islands are coated with an active substance on the front, with a metal layer coated on the active substance.

Both the pins and the island are coated with a metal layer on the back.

Both the pins and the islands are coated with an active substance on the back, with a metal layer coated on the active substance.

The pins are coated with a metal layer on the front and back, and the island is coated with a metal layer on the back.

The pins are coated with an active substance on the front and the back and the island is coated with an active substance on the back, with a metal layer coated on the active substance.

Both the pins and the island are coated with a metal layer on the front and back.

Both the pins and the islands are coated with an active substance on the front and back, with a metal layer coated on the active substance.

Said metal layer 4 covering on the substrate 1 can cover the substrate partially or entirely.

Said metal layer 4 is select form the group of Au, Ag, Cu, Sn, Ni, or Ni—Pd, and said metal layer can comprise one or more layers, or is distributed partially. Said active substance 3 is Ni, Pd, or Ni—Pd.

The method provided in the present invention comprises the following procedures:

1) Taking a metal substrate 6;

2) Bonding a film 7 on the front and back of the metal substrate 6;

3) Removing the film on the front of the metal substrate 6 partially, to expose the area to be semi-etched on the substrate 6;

4) Carrying out semi-etching in the area where the film 7 is removed in the previous procedure, to form a recessed semi-etched area 61 on the metal substrate 6 and form an island 1 and pins 2 in the form of bumps;

5) Removing the residual film on the metal substrate 6, to obtain a packaging substrate with flat bumps;

6) Carrying out further processing for the packaging substrate with flat bumps as required.

The further processing can comprises the following procedures:

1) Coating a film on the front and back of the metal substrate including the area with bumps again;

2) Removing the film on the metal substrate 6 partially, to expose the area to be coated with a metal layer subsequently;

3) Coating the area where the film is removed in the previous procedure with a metal layer;

4) Removing the residual film on the metal substrate 6.

An active substance can be coated before the metal layer is coated.

1. A packaging substrate with flat bumps for electronic devices, comprising an island 1 and lead pins, wherein the island 1 and lead pins are distributed on the front of the substrate in the form of bumps, and the bottoms of the bumps, that is the backs of island and pins, are connected to the substrate; in such an encapsulation structure for electronic device that is formed in the subsequent encapsulation process, the number of the islands can be one or several, and the pins can be arranged on one side, two sides, or three sides of the island, or around the island to form a structure with one or more rows of pins.

2. The packaging substrate with flat bumps for electronic devices according to claim 1, wherein the pins are coated with a metal layer on the front.

3. The packaging substrate with flat bumps for electronic devices according to claim 1, wherein the pins are coated with an active substance on the front, with a metal layer coated on the active substance.

4. The packaging substrate with flat bumps for electronic devices according to claim 1, wherein the pins and the island are coated with a metal layer on the front.

5. The packaging substrate with flat bumps for electronic devices according to claim 1, wherein the pins and the island are coated with an active substance on the front, with a metal layer coated on the active substance.

6. The packaging substrate with flat bumps for electronic devices according to claim 1, wherein the pins and the island are coated with a metal layer on the back.

7. The packaging substrate with flat bumps for electronic devices according to claim 1, wherein the pins and the island are coated with an active substance on the back, with a metal layer coated on the active substance.

8. The packaging substrate with flat bumps for electronic devices according to claim 1, wherein the pins are coated with a metal layer on the front and back, and the island is coated with a metal layer on the back.

9. The packaging substrate with flat bumps for electronic devices according to claim 1, wherein the pins are coated with an active substance on the front and back and the island is coated with an active substance on the back, with a metal layer coated on the active substance.

10. The packaging substrate with flat bumps for electronic devices according to claim 1, wherein the pins and the island are coated with a metal layer on the front and back.

11. The packaging substrate with flat bumps for electronic devices according to claim 1, wherein the pins and the island are coated with an active substance on the front and back, with a metal layer coated on the active substance.

12. The packaging substrate with flat bumps for electronic devices according to claim 2, wherein the island can be partially or entirely covered by the metal layer.

13. The packaging substrate with flat bumps for electronic devices according to claim 1, wherein said metal layer is select form the group of Au, Ag, Cu, Sn, Ni, or Ni—Pd, and said metal layer can be in one or more layers, or distributed partially.

14. The packaging substrate with flat bumps for electronic devices according to claim 3, wherein said active substance is Ni, Pd, or Ni—Pd.

15. A method of manufacturing the packaging substrate with flat bumps for electronic devices according to claim 1, wherein said method comprises the following procedures:
1) Taking a metal substrate;
2) Bonding a film on the front and back of the metal substrate;
3) Removing the film on the front of the metal substrate partially, to expose the area to be semi-etched on the substrate;
4) Carrying out semi-etching in the area where the film is removed in the previous procedure, to form a recessed semi-etched area on the metal substrate and form an island and pins in the form of bumps;
5) Removing the residual film on the metal substrate, to obtain a packaging substrate with flat bumps;
6) Carrying out further processing for the packaging substrate with flat bumps as required.

16. The method of manufacturing the packaging substrate with flat bumps for electronic devices according to claim 15, wherein the further processing comprises the following procedures:
1) Coating a film on the front and back of the metal substrate including the area with bumps again;
2) Removing the film on the front and back of the bumps on the metal substrate partially, to expose the area to be coated with a metal layer subsequently;
3) Coating the area where the film is removed in the previous procedure with a metal layer;
4) Removing residual film on the metal substrate.

17. The method of manufacturing the packaging substrate with flat bumps for electronic device according to claim 16, wherein an active substance is coated before the metal layer is coated.
